(19) United States
(12) Patent Application Publication
(10) Pub. No.: US 2011/0063846 A1
(43) Pub. Date: Mar. 17, 2011

(54) EXTENDED SOURCE LIGHT MODULE

(76) Inventors: Alexander Rizkin, Livermore, CA (US); Robert Tudhope, Liver more, CA (US); Keith Scott, Liver more, CA (US)

(21) Appl. No.: 12/879,817

(22) Filed: Sep. 10, 2010

Related U.S. Application Data
(60) Provisional application No. 61/242,221, filed on Sep. 14, 2009.

(51) Int. Cl. H01L 33/00; F21V 7/00

(52) U.S. Cl. 362/260; 257/98; 362/309; 257/E33.001

(57) ABSTRACT

A light source includes an extended light source, a first optical element, and a second optical element. The first optical element is coupled to the extended light source. The second optical element is coupled to the first optical element. The second optical element has a central reflective member and a refractive member surrounding the central reflective member.

### CROSS-REFERENCE TO RELATED APPLICATION(S)

Pursuant to 35 U.S.C. §119(e), this application claims the benefit of U.S. Provisional Application Ser. No. 61/242,221 filed on Sep. 14, 2009, the contents of which are hereby incorporated by reference herein in their entirety.

### BACKGROUND

1. Field

The present disclosure relates to an extended source light module.

2. Description of Related Art

LEDs have been developed for many years and have been widely used in various light applications. As LEDs are light-weight, consume less energy, and have a good electrical power to light conversion efficacy, they have been used to replace conventional light sources, such as incandescent lamps and fluorescent light sources. LEDs may be utilized in an array. An extended light source includes an LED array. Light from an extended light source is distributed by a reflector. However, there is a need in the art to improve the light distribution from an extended light source and to provide a predetermined light distribution as a function of the properties of the extended light source.

### SUMMARY

In one aspect of the disclosure, a light source includes an extended light source, a first optical element, and a second optical element. The first optical element is coupled to the extended light source. The second optical element is coupled to the first optical element. The second optical element has a central reflective member and a refractive member surrounding the central reflective member.

In one aspect of the disclosure, an apparatus configured to provide a predetermined light distribution includes a solid state light source, a first optical element, and a second optical element. The first optical element is coupled to the solid state light source. The first optical element has a first optical element input aperture, a first optical element output aperture, and side walls approximately symmetric with respect to a first optical axis. The solid state light source is located in the first optical element input aperture in a plane perpendicular to the first optical axis. The first optical element output aperture is configured to provide transformed light and untransformed light in a first predetermined light distribution. The transformed light is light reflected off the side walls. The untransformed light is light unreflected off the side walls. The side walls have a curvature to provide the transformed light at the first optical element output aperture such that the transformed light in superposition with the untransformed light has the first predetermined light distribution at the first optical element output aperture. The second optical element is coupled to the first optical element. The second optical element is located parallel to the plane. The second optical element has a secondary optical axis coaxial to the first optical axis. The second optical element has a second optical element input and a second optical element output. The second optical element output provides a second predetermined light distribution. The second optical element input has a reflective member located around the secondary optical axis and a refractive member located around the reflective member. The reflective member has a profile configured with respect to the first predetermined light distribution to reflect light towards the refractive member. The refractive member has a plurality of prismatic facets. Each of the prismatic facets has an individual inclination angle relative to the plane. Each individual inclination angle is configured as a function of an intensity of the transformed light, an intensity of light incident the reflective member, and an intensity of the untransformed light to produce the second predetermined light distribution with a predetermined light pattern. Light emitted by the solid state light source is transformed by the first optical element, the reflective member of the second optical element, and the refractive member of the second optical element to produce the second predetermined light distribution with the predetermined light pattern. The second predetermined light distribution is the predetermined light distribution.

In an aspect of the disclosure, a light emitting apparatus includes a solid state light source, a first optical element, and a second optical element. The first and second optical elements are configured to direct light emitted from the solid state light source to the second optical element. The second optical element includes a first member and a second member. The first member is configured to reflect at least a portion of the light to the second member. The second member is configured to refract at least a portion of the reflected light.

In an aspect of the disclosure, a light emitting apparatus includes a first optical element, a second optical element having a first member and a second member, and a solid state light source. The solid state light source is arranged with the first and second optical elements such that light emitted from the light source is directed by the first optical element to the second optical element where at least a portion of the light is reflected by the first member towards the second member and at least a portion of the reflected light is refracted by the second member.

### BRIEF DESCRIPTION OF THE DRAWINGS

FIG. 1 is a conceptual cross-sectional side view illustrating an example of an LED.

FIG. 2 is a conceptual top view illustrating an example of a light emitting element.

FIG. 3A is a conceptual top view illustrating an example of a white light emitting element.

FIG. 3B is a conceptual cross-sectional side view of the white light emitting element in FIG. 3A.

FIG. 4 is a side view of an extended source light module.

FIG. 5 is a bottom view of the secondary optical element.

FIG. 6A is a perspective exploded view of an LED array module.

FIG. 6B is a perspective of the LED array module of FIG. 6A.

FIG. 7 is a view of a heat sink.

FIG. 8 is a conceptual view illustrating a configuration for providing a predetermined light distribution.

### DETAILED DESCRIPTION

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element. In addition, when a first element is “coupled” to a second element, the first element may be directly connected to the second element or the first element may be indirectly connected to the second element with intervening elements between the first and second elements.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower” can therefore encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various aspects of an LED array module may be illustrated with reference to one or more exemplary configurations. As used herein, the term “exemplary” means “serving as an example, instance, or illustration,” and should not necessarily be construed as preferred or advantageous over other configurations of an LED array module disclosed herein.

Furthermore, various descriptive terms used herein, such as “on” and “transparent,” should be given the broadest meaning possible within the context of the present disclosure. For example, when a layer is said to be “on” another layer, it should be understood that that one layer may be deposited, etched, attached, or otherwise prepared or fabricated directly or indirectly above or below that other layer. In addition, something that is described as being “transparent” should be understood as having a property allowing no significant obstruction or absorption of electromagnetic radiation in the particular wavelength (or wavelengths) of interest, unless a particular transmittance is provided.

A solid state component is a device built entirely from solid materials in which the electrons are entirely confined within the solid material. The solid state component may be a light source. The light source may be constructed from an array of light emitting semiconductor cells. One example of a light emitting semiconductor cell is an LED. The LED is well known in the art, and therefore, will only briefly be discussed to provide a complete description of the invention.

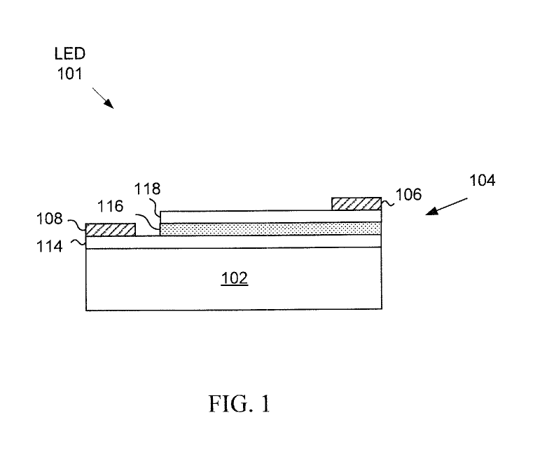

FIG. 1 is a conceptual cross-sectional side view illustrating an example of an LED. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes. A doped region with electrons may be referred to as an n-type semiconductor region. A doped region with holes may be referred to as a p-type semiconductor region. In LED applications, the semiconductor includes an n-type semiconductor region, a p-type semiconductor region, and an intervening active region between the n-type and p-type semiconductor regions. When a forward voltage sufficient to overcome the reverse electric field is applied across the p-n junction, electrons and holes are forced into the active region and combine. When electrons combine with holes, they fall to lower energy levels and release energy in the form of light.

Referring to FIG. 1, the LED 101 includes a substrate 102, an epitaxial-layer structure 104 on the substrate 102, and a pair of electrodes 106 and 108 on the epitaxial-layer structure 104. The epitaxial-layer structure 104 comprises an active region 116 sandwiched between two oppositely doped epitaxial regions. In this example, an n-type semiconductor region 114 is formed on the substrate 102 and a p-type semiconductor region 118 is formed on the active region 116, however, the regions may be reversed. That is, the p-type semiconductor region 118 may be formed on the substrate 102 and the n-type semiconductor region 114 may formed on the active region 116. As those skilled in the art will readily appreciate, the various concepts described throughout this disclosure may be extended to any suitable epitaxial-layer structure. Additional layers (not shown) may also be included in the epitaxial-layer structure 104, including but not limited to buffer, nucleation, contact and current spreading layers as well as light extraction layers.

The electrodes 106 and 108 may be formed on the surface of the epitaxial-layer structure 104. The p-type semiconductor region 118 is exposed at the top surface, and therefore, the p-type electrode 106 may be readily formed thereon. However, the n-type semiconductor region 114 is buried beneath the p-type semiconductor region 118 and the active region 116. Accordingly, to form the n-type electrode 108 on the n-type semiconductor region 114, a portion of the active region 116 and the p-type semiconductor region 118 is removed to expose the n-type semiconductor region 114 therebeneath. After this portion of the epitaxial-layer structure 104 is removed, the n-type electrode 108 may be formed.

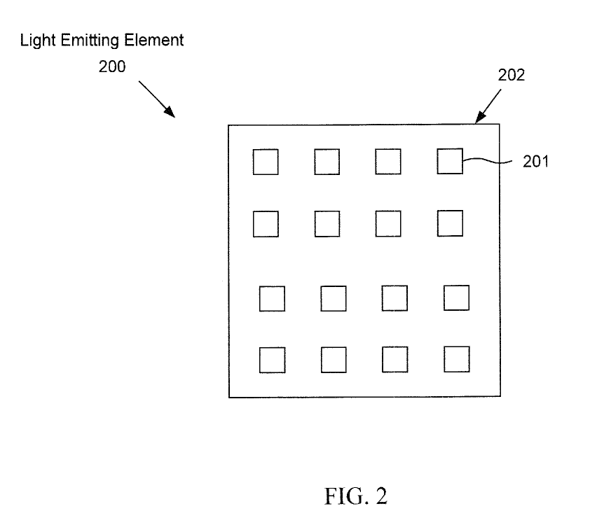

As discussed above, one or more light emitting cells may be used to construct a light emitting element. A light emitting element may be constructed in a 2-dimensional planar fashion. One example of a light emitting element will now be presented with reference to FIG. 2. FIG. 2 is a conceptual top view illustrating an example of a light emitting element. In this example, a light emitting element 200 is configured with multiple LEDs 201 arranged on a substrate 202. The substrate 202 may be made from any suitable material that provides mechanical support to the LEDs 201. Preferably, the material is thermally conductive to dissipate heat away from the LEDs 201. The substrate 202 may include a dielectric layer (not shown) to provide electrical insulation between the LEDs 201. The LEDs 201 may be electrically coupled in parallel and/or series by a conductive circuit layer, wire bonding, or a combination of these or other methods on the dielectric layer.

The light emitting element may be configured to produce white light. White light may enable the light emitting element to act as a direct replacement for conventional light sources used today in incandescent, halogen and fluorescent lamps. There are at least two common ways of producing white light. One way is to use individual LEDs that emit wavelengths (such as red, green, blue, amber, or other colors) and then mix all the colors to produce white light. The other way is to use a phosphor material or materials to convert monochromatic light emitted from a blue or ultra-violet (UV) LED to broad-spectrum white light. The present invention, however, may be practiced with other LED and phosphor combinations to produce different color lights.

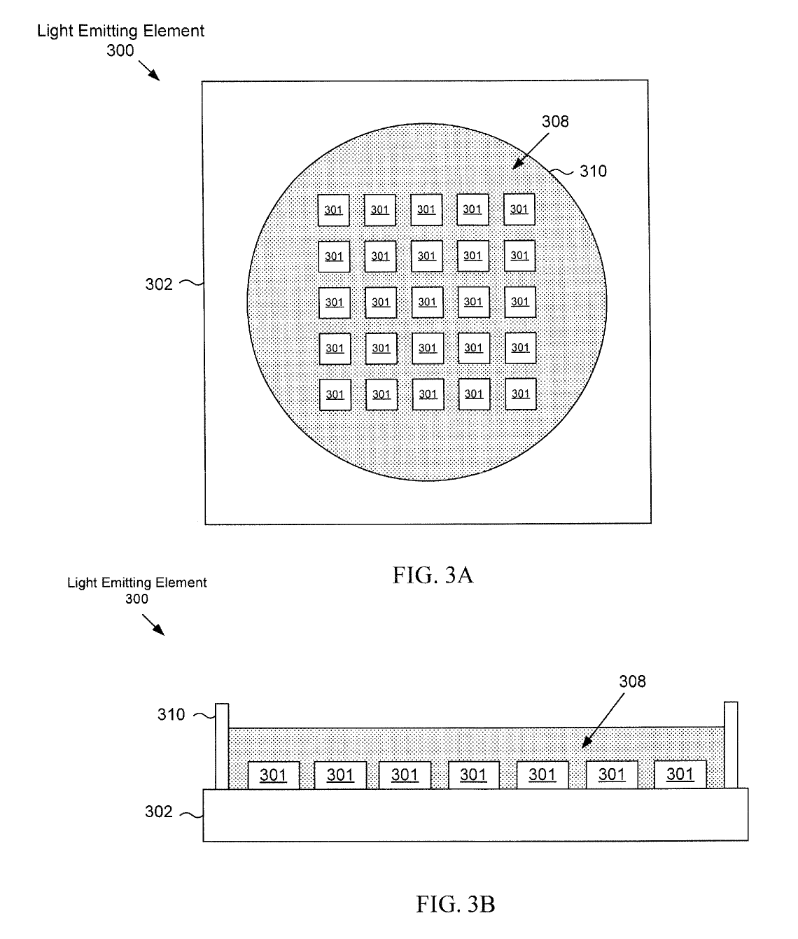

An example of a white light emitting element will now be presented with reference to FIGS. 3A and 3B. FIG. 3A is a conceptual top view illustrating an example of a white light emitting element and FIG. 3B is a conceptual cross-sectional side view of the white light emitting element in FIG. 3A. The white light emitting element 300 is shown with a substrate 302 which may be used to support multiple LEDs 301. The substrate 302 may be configured in a manner similar to that described in connection with FIG. 2 or in some other suitable way. A phosphor material 308 may be deposited within a cavity defined by an annular, or other shape, or other boundary 310 that extends circumferentially, or in any shape, around the upper surface of the substrate 302. The annular boundary 310 may be formed with a suitable mold, or alternatively, formed separately from the substrate 302 and attached to the substrate 302 using an adhesive or other suitable means. The phosphor material 308 may include, by way of example, phosphor particles suspended in an epoxy, silicone, or other carrier or may be constructed from a soluble phosphor that is dissolved in the carrier.

In an alternative configuration of a white light emitting element, each LED may have its own phosphor layer. As those skilled in the art will readily appreciate, various configurations of LEDs and other light emitting cells may be used to create a white light emitting element. Moreover, as noted earlier, the present invention is not limited to solid state lighting devices that produce white light, but may be extended to solid state lighting devices that produce other colors of light.

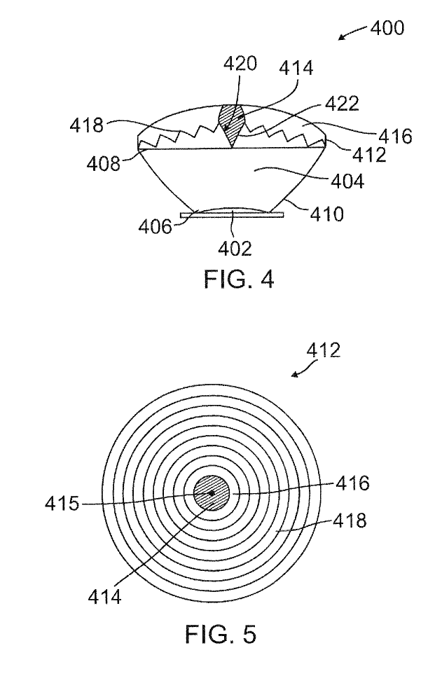

FIG. 4 is a side view of an extended source light module 400. The module 400 includes an extended light source 402, which may be a multi-chip LED array. The extended light source 402 is coupled to a primary optical element 404. The primary optical element 404 has a primary optical element input aperture 406 and a primary optical element output aperture 408. The primary optical element 404 further includes a primary optical element side wall 410 that is conically shaped to distribute light emitted from the extended light source 402. A secondary optical element 412 is coupled to the primary optical element 404. The secondary optical element 412 includes a secondary optical element first member 414 and a secondary optical element second member 416. The secondary optical element first member 414 has a reflective surface 420 and the secondary optical element second member 416 has prismatic facets 418 to refract light. The secondary optical element first member 414 has a conical lower surface 422 that is reflective in order to reflect light from the extended light source 402 into the prismatic facets 418. In one configuration, the secondary optical element 412 is one component, with the first member 414 and the second member 416 formed with different properties in order to reflect and to refract light, respectively. In another configuration, the secondary optical element 412 is two separate components, with the first member 414 and the second member 416 being separate components coupled together.

The module 400 provides a predetermined light distribution from the extended light source 402. As discussed supra, the module 400 includes an extended light source 402, a primary optical element 404, and a secondary optical element 412. The extended light source 402 has a predetermined spatial light distribution. The primary optical element 404 collects, redirects, and redistributes portions of the light emitted from the extended light source 402. The extended light source 402 is located in the input aperture 406 in a plane perpendicular to an optical axis of the primary optical element 404. The primary optical element 404 creates in superposition with an untransformed portion of the emitted light a precalculated intensity distribution across the output aperture 408 through a calculation of a profile of the side wall 410, located between the input aperture 406 and the output aperture 408, as a function of a given specific extended light source 402.

The secondary optical element 412 is located in a plane of the output aperture 408 of the primary optical element 404 with an optical axis coaxial to the optical axis of the primary optical element 404. The secondary optical element 412 has a lower surface and an upper surface. The lower surface receives light and the upper surface emits the received light. The secondary optical element 412 creates a predetermined light pattern. The secondary optical element 412 includes a first member 414 and a second member 416. The first member 414 is located around the optical axis of the secondary optical element 404. The first member 414 has a reflective surface with a profile calculated as a function of the intensity distribution across the output aperture 408. The first member 414 redistributes and redirects light received from the primary optical element 404 towards the second member 416, which is disposed around the first member 414. The second member 416 includes a number of prismatic facets 418. Each of the prismatic facets 418 has an individual inclination angle relative to a reference plane disposed perpendicular to the optical axis. The individual inclination angle for each of the prismatic facets is calculated as a function of the actual intensity of the direct incident light from the primary optical element 404, an intensity of light reflected from the first member 414, and the desired intensity of the outgoing light in a preselected/predetermined direction.

Accordingly, the module 400 provides a triple transformation of light, with the primary optical element providing a first transformation as a function of the curvature of the side wall 410 and the size of the input aperture 406 and the output aperture 408, the secondary optical element first member 414 providing a second transformation as a function of its size and the curvature of its reflective lower surface 422, and the secondary optical element second member 416 providing a third transformation as a function of the individual inclination angle of its prismatic facets 418. The triple transformation of the module 400 produces a predetermined light envelope and creates a predetermined light pattern.

The extended light source 402 may be a multi-chip LED array. The module 400 may include a phosphor layer on the extended light source 402 or a remote phosphor located remote from the extended light source 402. The secondary optical element 412 may be rotationally symmetrical around the optical axis and the prismatic facets 418 may be in circular relation. Alternatively, the secondary optical element 412 may be asymmetrical around the optical axis and the prismatic facets 418 may be in non-circular relation. The outer surface of the secondary optical element second member 416 may be shaped to be rotationally symmetric around the optical axis. Alternatively, the outer surface of the secondary optical element second member 416 may have an arbitrary shape with a shape asymmetric with respect to the optical axis.

The secondary optical element 412 may be a light shaping element and therefore may shape the light that passes through the secondary optical element 412. A simple glass cover is an example of an element that is not a light shaping element. The secondary optical element 412 may be a non-Lambertian diffuser, and therefore the radiant intensity of the light is not directly proportional to the cosine of the angle between an observer's line of sight and the normal to the surface. As such, when the secondary optical element 412 is a non-Lambertian diffuser, the light from the secondary optical element 412 does not appear to have the same radiance from different observer angles.

FIG. 5 is a bottom view of the secondary optical element 412. The secondary optical element 412 has a central portion, referred to as the first member 414, around point 415 that reflects light. Point 415 is the bottom point of the conically shaped portion of the first member 414. An outer portion, outside of the central portion, referred to as the second member 416, has a plurality of facets 418 that refract light.

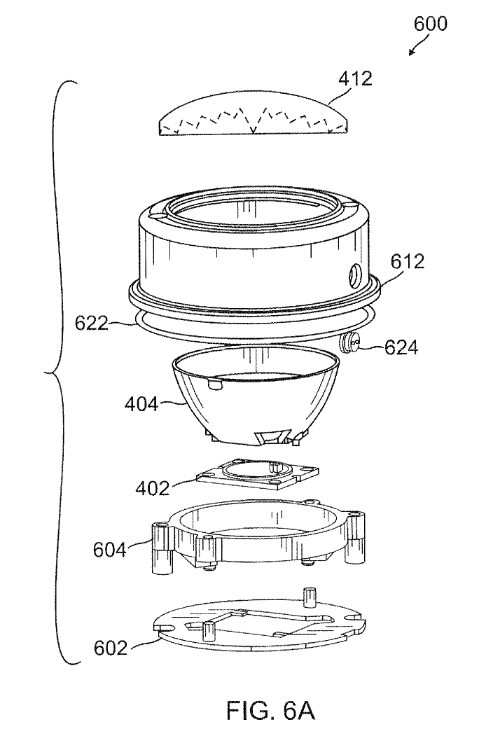

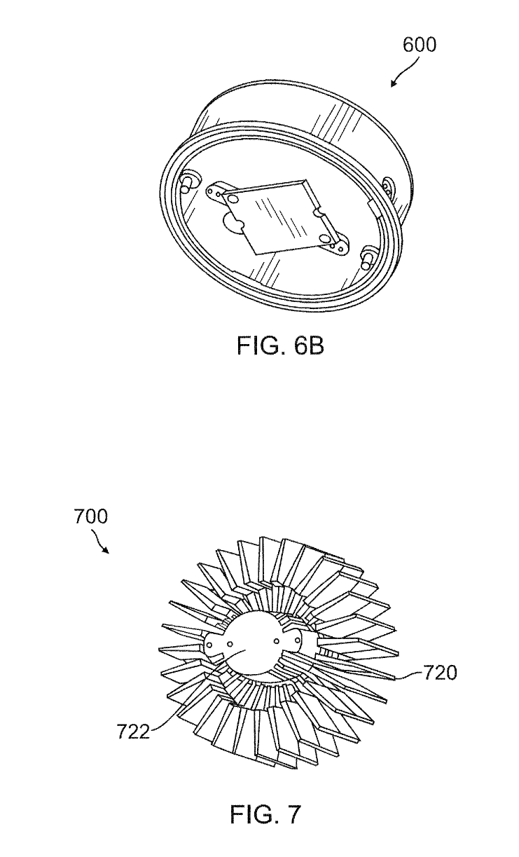

FIG. 6A is a perspective exploded view of an LED array module 600. FIG. 6B is a perspective view of the LED array module 600. As shown in FIG. 6A, the LED array module 600 includes a printed circuit board 602, a frame 604 attachable to the printed circuit board 602, an LED array 402 attachable to the frame 604, a reflector 404 for transforming light from the LED array 402, a cover 612 for covering the LED array 402 and the reflector 404, and a secondary optic 412 for further transforming the light emitted from the LED array 402. The LED array 402 may be the light emitting element 200 or the light emitting element 300. The LED array 402 is sealed within the cover 612 with the silicone o-ring 622 and the rubber grommet 624 that is insertable into a hole in the side of the cover 612.

FIG. 7 is a view of a heat sink 700. The heat sink 700 may be aluminum or an aluminum alloy. The heat sink 700 has a plurality of arms 720 that extend from a core 722. The heat sink 700 further includes holes for allowing the module 600 to attach. As shown in FIG. 7, the heat sink 700 is the base of the assembly. However, the heat sink may also be configured to serve as the assembly enclosure.

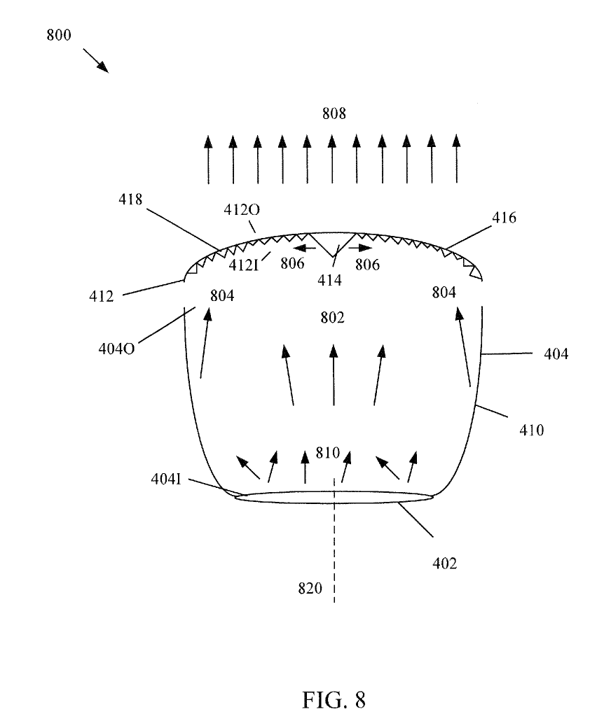

FIG. 8 is a conceptual view illustrating a configuration for providing a predetermined light distribution. The apparatus 800 includes a solid state component 402 (e.g., LED array), a primary optical element 404, and a secondary optical element 412. The primary optical element 404 is coupled to the solid state component 402. The primary optical element 404 has a primary optical element input aperture 404I, a primary optical element output aperture 404O, and side walls 410 approximately symmetric with respect to a primary optical axis 820. The solid state component 402 is located in the primary optical element input aperture 404I in a plane perpendicular to the primary optical axis 820. The primary optical element output aperture 404O is configured to provide transformed light 804 and untransformed light 802 in a primary predetermined light distribution 802/804. The transformed light 804 is light reflected off the side walls 410. The untransformed light 802 is light unreflected off the side walls. The side walls 410 have a curvature to provide the transformed light 804 at the primary optical element output aperture 404O such that the transformed light 804 in superposition with the untransformed light 802 has the primary predetermined light distribution 802/804 at the primary optical element output aperture 404O.

The secondary optical element 412 is coupled to the primary optical element 404. The secondary optical element is located parallel to the plane of the primary optical element input aperture 404I. The secondary optical element 412 has a secondary optical axis 820 coaxial to the primary optical axis 820 (i.e., the axes are the same). The secondary optical element 412 has a secondary optical element input 412I and a secondary optical element output 412O. The secondary optical element output 412O provides the predetermined light distribution 808. The secondary optical element input 404I has a reflective member 414 located around the secondary optical axis 820 and a refractive member 416 located around the reflective member 414. The reflective member 414 has a profile (e.g., approximately conically shaped) configured with respect to the primary predetermined light distribution 802/804 to reflect light 806 towards the refractive member 416. The refractive member 416 has a plurality of prismatic facets 418. Each of the prismatic facets 418 has an individual inclination angle relative to the plane of the primary optical element input aperture 404I. Each individual inclination angle is configured as a function of an intensity of the transformed light 804, an intensity of light 806 incident the reflective member 414, an intensity of the untransformed light 802, and an intensity of light exiting the secondary optical element output 808.

The light 810 emitted by the solid state component 402 is transformed by the primary optical element 404, the reflective member 414, and the refractive member 416 of the secondary optical element 412 to produce the predetermined light distribution with a predetermined light pattern 808.

The various aspects of this disclosure are provided to enable one of ordinary skill in the art to practice the present invention. Modifications to various aspects of an LED array module presented throughout this disclosure will be readily apparent to those skilled in the art, and the concepts disclosed herein may be extended to other applications. Thus, the claims are not intended to be limited to the various aspects of an LED array module presented throughout this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A light emitting apparatus, comprising:
a solid state light source;
a first optical element coupled to the solid state light source; and
a second optical element coupled to the first optical element;
wherein the second optical element comprises a reflective portion and a refractive portion surrounding the reflective portion; and the reflective portion is in a center of the second optical element and comprises a protrusion that extends toward the first optical element.

2. The apparatus of claim 1, wherein the refractive portion comprises a plurality of facets extending toward the first optical element.

3. The apparatus of claim 1, wherein the solid state light source comprises an extended light source.

4. The apparatus of claim 3, wherein the extended light source comprises an extended white light source.

5. The apparatus of claim 3, wherein the extended light source comprises an array of light emitting semiconductor cells.

6. The apparatus of claim 1, wherein the solid state light source has a phosphor layer.

7. The apparatus of claim 1, wherein the second optical element is a light shaping element.

8. The apparatus of claim 7, wherein the light shaping element is a non-Lambertian diffuser.

9. The apparatus of claim 1, further comprising:
a frame attached to the solid state light source;
a cover over the second optical element, the first optical element, the solid state light source, and the frame;
an o-ring coupled to a bottom of the cover; and
a grommet insertable within the cover.

10. The apparatus of claim 9, further comprising a printed circuit board below the frame and coupled to the solid state light source, wherein the cover is over the printed circuit board.

11. The apparatus of claim 10, further comprising a heat sink coupled to the solid state light source.

12. The apparatus of claim 11, wherein the heat sink is a base of the apparatus.

13. The apparatus of claim 11, wherein the heat sink at least partially encloses the solid state light source.

14. An apparatus configured to provide a predetermined light distribution, comprising:
an extended light source with described spatial light distribution;
a first optical element having an input aperture on a first end and an output aperture on a second end, the second end located on the opposite side of the optical element, and side walls located between first end and second end around optical element optical axis; the profile of side walls calculated as a function of specific spatial light distribution of extended light source located in input aperture in plane perpendicular to first optical element optical axis, wherein portion of light emitted by light source reflected from side walls in direction of output aperture to create in superposition with non-reflected portion of emitted light precalculated intensity distribution across side output aperture.
a second optical element coupled to the first optical element, the second optical element located in plane of first optical element's output aperture with optical axis coaxial to first optical element's optical axis, having first end receiving the light from first optical element and the second end located on opposite side from the first end, the second end emits outgoing light, creating predetermined light pattern, wherein second optical element having a reflective member located around the secondary optical axis and a refractive member located around the reflective member; the reflective member having a profile configured with respect to the first predetermined light distribution to reflect light towards the refractive member; the refractive member having a plurality of prismatic facets, each of the prismatic facets having an individual inclination angle relative to said plane, each individual inclination angle being configured as a function of an intensity of the transformed light, an intensity of light incident the reflective member, and an intensity of the untransformed light to produce the second predetermined light distribution with a predetermined light pattern,
wherein light emitted by the solid state light source is transformed by the first optical element, the reflective member of the second optical element, and the refractive member of the second optical element to produce the second predetermined light distribution with the predetermined light pattern, the second predetermined light distribution being said predetermined light distribution.

15. The apparatus of claim 14, wherein the second optical element is rotationally symmetrical around the second optical axis having second member prismatic facets in non-circular relation.

16. The apparatus of claim 14, wherein the second optical element is asymmetrical around the optical axis having second member prismatic facets in non-circular relation.

17. The apparatus of claim 14, wherein a second end of the second optical element is shaped as a rotationally symmetrical around optical axis refractive optical element.

18. The apparatus of claim 14, wherein a second end of the second optical element is shaped as an asymmetrical refractive optical element.

19. The apparatus of claim 14, wherein the reflective portion comprises a protrusion that extends toward the first optical element.

20. The apparatus of claim 14, wherein the prismatic facets extend toward the first optical element.

21. The apparatus of claim 14, wherein the solid state light source comprises an extended light source.

22. The apparatus of claim 21, wherein the extended light source comprises an extended white light source.

23. The apparatus of claim 21, wherein the extended light source comprises an array of light emitting semiconductor cells.

24. The apparatus of claim 14, wherein the solid state light source has a phosphor layer.

25. The apparatus of claim 14, wherein the second optical element is a light shaping element.

26. The apparatus of claim 25, wherein the light shaping element is a non-Lambertian diffuser.

27. The apparatus of claim 14, further comprising:
a frame attached to the solid state light source;
a cover over the second optical element, the first optical element, the solid state light source, and the frame;
an o-ring coupled to a bottom of the cover; and
a grommet insertable within the cover.

28. The apparatus of claim 27, further comprising a printed circuit board below the frame and coupled to the solid state light source, wherein the cover is over the printed circuit board.

29. The apparatus of claim 28, further comprising a heat sink coupled to the solid state light source.

30. The apparatus of claim 29, wherein the heat sink is a base of the apparatus.

31. The apparatus of claim 29, wherein the heat sink at least partially encloses the solid state light source.

32. A light emitting apparatus, comprising:
a solid state light source;
a first optical element coupled to the solid state light source; and
a second optical element coupled to the first optical element,
wherein the first optical element is configured to direct light emitted from the solid state light source to the second optical element,
wherein the second optical element comprises a first member and a second member, the first member being configured to reflect at least a portion of the light to the second member, and the second member being configured to refract at least a portion of the reflected light.

33. The apparatus of claim 32, wherein the first member is in a center of the second optical element and comprises a conically shaped protrusion that extends toward the first optical element.

34. The apparatus of claim 32, wherein the second member comprises a plurality of facets extending toward the first optical element.

35. The apparatus of claim 32, wherein the solid state light source comprises an extended light source.

36. The apparatus of claim 35, wherein the extended light source comprises an extended white light source.

37. The apparatus of claim 35, wherein the extended light source comprises an array of light emitting semiconductor cells.

38. The apparatus of claim 32, wherein the solid state light source has a phosphor layer.

39. The apparatus of claim 32, wherein the second optical element is a light shaping element.

40. The apparatus of claim 39, wherein the light shaping element is a non-Lambertian diffuser.

41. The apparatus of claim 32, further comprising:
a frame attached to the solid state light source;
a cover over the second optical element, the first optical element, the solid state light source, and the frame;
an o-ring coupled to a bottom of the cover; and
a grommet insertable within the cover.

42. The apparatus of claim 41, further comprising a printed circuit board below the frame and coupled to the solid state light source, wherein the cover is over the printed circuit board.

43. The apparatus of claim 42, further comprising a heat sink coupled to the solid state light source.

44. The apparatus of claim 43, wherein the heat sink is a base of the apparatus.

45. The apparatus of claim 43, wherein the heat sink at least partially encloses the solid state light source.

46. A light emitting apparatus, comprising:
a first optical element;
a second optical element having a first member and a second member; and
a solid state light source arranged with the first and second optical elements such that light emitted from the light source is directed by the first optical element to the second optical element where at least a portion of the light is reflected by the first member towards the second member and at least a portion of the reflected light is refracted by the second member.

47. The apparatus of claim 46, wherein the first member is in a center of the second optical element and comprises a conically shaped protrusion that extends toward the first optical element.

48. The apparatus of claim 46, wherein the second member comprises a plurality of facets extending toward the first optical element.

49. The apparatus of claim 46, wherein the solid state light source comprises an extended light source.

50. The apparatus of claim 49, wherein the extended light source comprises an extended white light source.

51. The apparatus of claim 49, wherein the extended light source comprises an array of light emitting semiconductor cells.

52. The apparatus of claim 46, wherein the solid state light source has a phosphor layer.

53. The apparatus of claim 46, wherein the second optical element is a light shaping element.

54. The apparatus of claim 53, wherein the light shaping element is a non-Lambertian diffuser.

55. The apparatus of claim 46, further comprising:
a frame attached to the solid state light source;
a cover over the second optical element, the first optical element, the solid state light source, and the frame;
an o-ring coupled to a bottom of the cover; and
a grommet insertable within the cover.

56. The apparatus of claim 55 further comprising a printed circuit board below the frame and coupled to the solid state light source, wherein the cover is over the printed circuit board.

57. The apparatus of claim 56, further comprising a heat sink coupled to the solid state light source.

58. The apparatus of claim 57, wherein the heat sink is a base of the apparatus.

59. The apparatus of claim 57, wherein the heat sink at least partially encloses the solid state light source.
